(19) United States
(12) Patent Application Publication
(10) Pub. No.: US 2023/0143313 A1
(43) Pub. Date: May 11, 2023

(54) A NON-ISOLATED DRIVER FOR LED LIGHTING

(71) Applicant: SIGNIFY HOLDING B.V., EINDHOVEN (NL)

(72) Inventors: Guangyi LUO, SHANGHAI (CN); Liang SHI, SHANGHAI (CN); Kang LI, SHANGHAI (CN); Gang WANG, SHANGHAI (CN); Zhenyi ZHENG, SHANGHAI (CN); Bo CAI, SHANGHAI (CN); Lei ZHOU, SHANGHAI (CN)

(21) Appl. No.: 17/918,494

(22) PCT Filed: Apr. 8, 2021
(86) PCT No.: PCT/EP2021/059205

§ 371 Date: Oct. 12, 2022

(30) Foreign Application Priority Data
Apr. 24, 2020 (WO) PCT/CN2020/086689
Jun. 11, 2020 (EP) 20179430.2

(51) Int. Cl. H05B 45/50; H02M 3/158; G01R 31/52; H05B 47/26

(52) U.S. Cl. CPC H05B 45/50; G01R 31/52; H02M 3/158; H05B 47/26

(57) ABSTRACT

A non-isolated LED driver has a converter which delivers first and second outputs. A sense circuit is coupled to both the first output and the second output, between the converter and an LED unit. The currents at the first output and the second output are compared to obtain a difference therebetween, and a leakage fault is determined based on an alternating current component of the difference. This avoids the need for an isolated driver, by instead detecting a leakage fault and then taking appropriate safety actions.

### FIELD OF THE INVENTION

The invention relates to a non-isolated driver for LED lighting.

### BACKGROUND OF THE INVENTION

Isolated drivers are often used in outdoor lighting systems, in order to provide a safety function even if there is water ingress into the outdoor luminaire. This water ingress may electrically connect electrical parts of the driver to the metal enclosure when a person just touches the metal enclosure. The isolation for example involves use of a transformer at the output stage of the driver. By using an isolated driver, the person would not be electrically exposed to the input of the driver, 220 V rms AC mains etc., via the water ingress and the housing.

In order to achieve smaller size and higher efficiency, it would be desirable to enable use of a non-isolated driver. However, a non-isolated driver does not possess the inherent electrical isolation between the output and the input, and so it is instead required to address the safety issues based on monitoring leakage events.

A non-isolated driver is normally used in a so-called class 1 luminaire, which requires solid grounding at the luminaire level to prevent current flowing through the human body in the event of a leakage. However, in real applications, the grounding may not be guaranteed. If there is water leakage into a luminaire, such as at the driver’s output side or at the LED board, so that the LED output is electrically coupled to the metal enclosure of luminaire, the luminaire will become unsafe because the non-isolated driver can directly deliver electrically energy from the input such as high voltage 220 V rms AC mains to the metal enclosure of the luminaire. This presents a safety issue for a person who touches the metal enclosure of the working luminaire.

There is a need for a safety circuit which can tolerate a poor ground connection and remain safe for a user to touch the LED lighting unit enclosure when using a non-isolated driver.

KR20150000647A discloses a circuit that can detect leakage in a LED streetlight. A set of differential coils is positioned at the live and neutral input of the whole LED streetlight.

US20160118784A1 discloses a non-isolated power supply for LEDs, which determines a ground fault via detecting a current difference ΔI of currents in a supply line and a return line between a buck converter and the LEDs.

### SUMMARY OF THE INVENTION

It is a concept of the invention to use a non-isolated converter to drive a LED lighting unit using first and second outputs. A sense circuit is coupled to both the first output and the second output, hence between the non-isolated driver and the LED unit, for example within a luminaire. The currents at the first output and the second output are compared to obtain a difference therebetween, and a fault is determined based on the difference. More specifically, an AC component of the difference is detected to determine the fault.

The use of a non-isolated driver is thereby enabled, with the sense circuit integrated between the driver and the LED lighting unit, so the sense circuit could also reside within the driver box, and thereby in a luminaire. Although it is known to use differential coils to detect current leakage, the use in combination with a non-isolated driver has not been considered, to solve its inherent drawback of non-isolation and the risk resulted thereby. By using the embodiments of the invention, the cost of the luminaire is greatly reduced and safety is also ensured.

The invention is defined by the claims.

According to examples in accordance with an aspect of the invention, there is provided a non-isolated driver for a LED lighting unit, comprising:
a non-isolated converter with an input to be connected to a power supply, a converting circuit to convert power from the power supply, and an output arrangement to be connected to the LED lighting unit, wherein said output arrangement comprises a first output for delivering current and a second output for receiving returned current, wherein the output of the non-isolated driver is coupled to the power supply electrically without an electrical isolator;
a sense circuit coupled to both the first output and the second output;
a comparing circuit to compare currents at the first output and the second output and obtain a difference therebetween; and
a controller adapted to determine whether there is a ground fault according to whether an alternating current component of the difference is detected.

This driver makes use of a sense circuit within the driver for enabling leakage current, and hence ground fault, detection. This may be used as a safety measure, for example for outdoor loads. It enables a non-isolated converter circuit to be used (and with no isolation between the power supply and the output of the driver), thereby allowing a low cost and efficient converter circuit to have a safety protection mechanism instead of requiring transformer isolation. The ground fault to be detected is for example external to the output, and for example caused by conduction through the human body. Specifically, the aspect analyzes the AC component of the difference in current to deduce the leakage, because the voltage potential at the neutral is AC thus the LED board’s leakage with respect to the neutral also has an AC component. This mitigates the problem that the variance in the sensing element may generates a difference even if the in and out current are the same.

Here the term “isolated” and hence “isolator” or “electrical isolator” means any means that prevents a direct electrical power-level transfer. An electrical isolator for example is a transformer, in which the power is transferred in a transition between an electric field and a magnetic field and between the magnetic field and an electric field. In this sense, a “non-isolated” driver is for example a buck converter, boost converter, buck-boost converter, Cuk converter, SEPIC converter, or the like, in which the driver output can access the input electrical power directly for power-level transfer, for example via an inductor or even a power-level capacitor (as in a Cuk and SEPIC converter). If a human touches the output, the high power or voltage level of the AC mains would flow through the human body and return to the input via ground, namely forming a power level loop and hence a risk to the human.

By comparison, an isolated driver is, for example, a transformer-based converter, such as a flyback converter, boost-integrated flyback (BiFRED) converter, an LLC or LCC converter, etc., in which the driver output cannot access the input electrical power directly. The input is instead connected to a primary winding of a transformer and the output is connected to a secondary winding of a transformer, and the two windings are only magnetically coupled for power-level electrical coupling (there could be a very small Y capacitor connected across the two windings but that does not allow power level energy transfer and the present application does not consider such a capacitor as an electrical isolator).

If a human touches the output in an isolated system, the output with the LED is itself a closed loop without involving the ground, therefore there would not likely be power flow from the input through the human body and a return to the input via ground, and hence the risk to the human is avoided.

The sense circuit is coupled to the first and second outputs. Thus, a standard non-isolated driver may be used without modification. Similarly, the sense circuit may be before the input of the LED lighting unit. Thus, a standard LED board may also be used.

Because the output of a non-isolated driver is electrically coupled to the power supply, for example via an inductor, or linear switch, etc. without an isolator, there is the potential for direct electric leakage from the power supply to the output. The sensing function addresses this possible leakage issue.

The sense circuit may comprise an inductor arrangement magnetically coupled to the first output and the second output.

The inductor arrangement is used to detect a magnetic field resulting from unequal delivered and returned currents. The sense circuit for example comprises a zero-phase current transformer.

The sense circuit may be provided between a first circuit board of the non-isolated converter and a second circuit board of the LED lighting unit, and the controller is adapted to determine whether there is a ground fault at the LED lighting unit according to the difference. Thus, existing first and second circuit board designs may be used.

The controller may be adapted to identify a ground fault which may be caused by human body conduction if the current difference is above a lower threshold. The lower threshold is for example between 1mA and 10mA, for example 5mA.

The controller may be adapted to determine that a protection function should be implemented if the current difference reaches an upper threshold. The upper threshold is for example between 5mA and 50mA, for example 20mA.

The controller is for example adapted to identify no ground fault if the current difference is below the lower threshold. This lower threshold may correspond to a parasitic leakage level of the driver or luminaire.

The driver may further comprise a switch arrangement for isolating the first output and the second output, and thereby the LED lighting unit, from the converting circuit if the controller determines a ground fault requiring a protection function.

The switch arrangement for example comprises a respective switch at each of the first and second outputs. This provides a safety cutoff function.

In an embodiment, the switch arrangement comprises a first switch (T2) and a second switch (T1), the sense circuit (40) is adapted to sense the difference of the voltages across the first switch (T2) and the second switch (T1) as the difference of current. This embodiment re-uses the safety cut off switch also for sensing function, there is no need to use dedicated sensing resistor or coil, and cost and size is reduced.

In a further embodiment, the controller is adapted to determine that a protection function should be implement if an alternating component of the current different reaches a certain threshold, normally 10mA. Meaning if the AC component is higher than 10mA, it is determined that a leakage happens. This embodiment ignores some AC noises and increases the robustness of the determination.

A locking circuit may be provided to maintain the isolated state of the switch even the difference recovers from a value indicative of a ground fault requiring a protection function. This provides a safety latching function. In this case, a re-start on of the driver or luminaire can reset the locking circuit and power the LED again.

The driver may further comprise a filtering circuit to filter the current difference and to provide the filtered current difference to the controller. This prevents false triggering caused by high frequency noise, for example.

The converting circuit may comprise one of:
a buck converter;
a buck-boost converter; and
a boost converter.

In a further embodiment, the difference of current can be made artificially in response to an overcurrent event such that the same ground fault detection can be used for overcurrent detection (and protection). In this embodiment, the non-isolated driver further comprising:
an impedance between the sense circuit and the second output of the non-isolated driver;
a voltage triggered circuit between an interconnection of a cathode of the LED lighting unit and the sense circuit, and the second output,
wherein the voltage triggered circuit is adapted to conduct when a voltage across it exceeds a certain threshold, said voltage is caused by a current exceeding an overcurrent threshold applied on the impedance, and
the voltage triggered circuit, when it conducts, is adapted to divert a current from the sense circuit such that the comparing circuit is adapted to obtain the difference and the controller is adapted to treat the difference effectively as a ground fault.

In this embodiment, the voltage triggered circuit, in case of overcurrent, creates a difference of currents in the positive line and the negative line with respect to the sense circuit, thereby mimicking a leakage. In turn, the controller treats the difference effectively as a ground fault thus the non-isolated driver can both detects real ground leakage and overcurrent with the same topology.

Preferably, the impedance comprises a resistor or an on resistance of a safety switch, the resistance of the sense circuit is substantially neglectable, and the voltage triggered circuit comprises a Zener arrangement whose forward voltage is less than the product of the overcurrent threshold and the resistance of the resistor or the on resistance but larger than the product of a nominal operating current and the resistance of the resistor or the on resistance, and the controller is adapted to cut off the non-isolated driver from the LED lighting unit.

This embodiment provides low cost implementations for the impedance and the voltage triggered circuit.

The invention also provides a lighting circuit comprising:
the driver as defined above; and
the LED lighting unit.

The lighting circuit may be comprised in an outdoor luminaire.

These and other aspects of the invention will be apparent from and elucidated with reference to the embodiment(s) described hereinafter.

### BRIEF DESCRIPTION OF THE DRAWINGS

For a better understanding of the invention, and to show more clearly how it may be carried into effect, reference will now be made, by way of example only, to the accompanying drawings, in which:

FIG. 1 shows a luminaire connected to main live and neutral of a mains supply;

FIG. 2 shows general architecture of a driver of the invention;

FIG. 3 shows in simplified form the functions of the protection circuit;

FIG. 4 shows an example of circuit implementation and simulation;

FIG. 5 shows simulation results for the circuit of FIG. 4;

FIG. 6 shows a first example of how the stop signal is used;

FIG. 7 shows a relay based solution in more detail;

FIG. 8 shows a MOSFET based solution in more detail;

FIG. 9 shows another embodiment and

FIG. 10 shows an overcurrent protection by re-using the ground leakage protection circuit of the embodiment of the invention.

### DETAILED DESCRIPTION OF THE EMBODIMENTS

The invention will be described with reference to the Figures.

It should be understood that the detailed description and specific examples, while indicating exemplary embodiments of the apparatus, systems and methods, are intended for purposes of illustration only and are not intended to limit the scope of the invention. These and other features, aspects, and advantages of the apparatus, systems and methods of the present invention will become better understood from the following description, appended claims, and accompanying drawings. It should be understood that the Figures are merely schematic and are not drawn to scale. It should also be understood that the same reference numerals are used throughout the Figures to indicate the same or similar parts.

The invention provides a non-isolated LED driver which has a converter which delivers an output on first and second outputs. A sense circuit is coupled to both the first output and the second output, between the converter and an LED unit. The currents at the first output and the second output are compared to obtain a difference therebetween, and a leakage fault is determined based on the difference. This avoids the need for an isolated driver, by instead detecting a leakage fault and then taking appropriate safety actions.

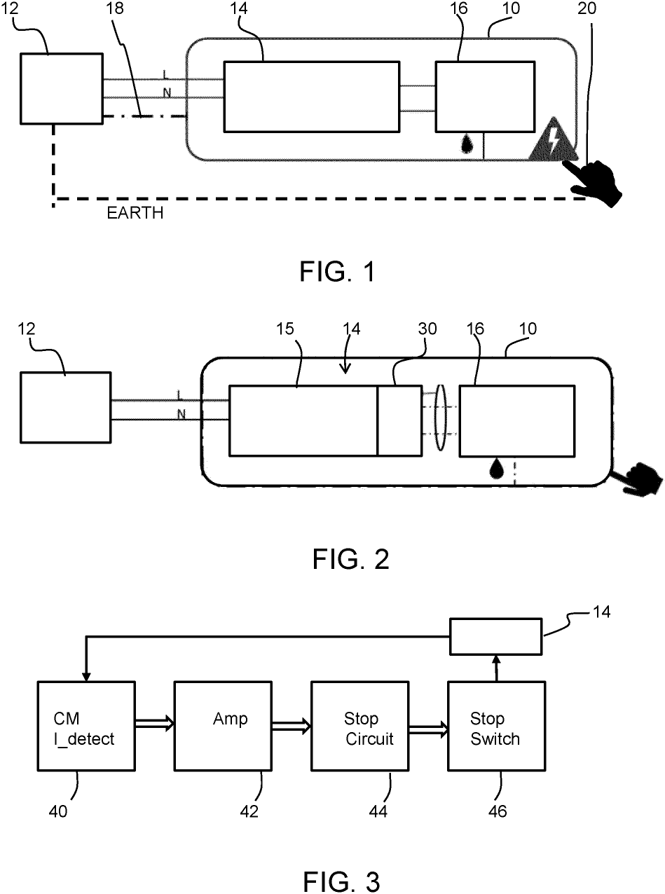

FIG. 1 shows a luminaire 10 connected to main live and neutral L, N of a mains supply 12. The luminaire has a non-isolated driver 14 and a LED unit 16. For a luminaire with a non-isolated driver, the luminaire is required to have solid grounding 18 of the luminaire. However, if this grounding 18 is not guaranteed, in particular when water leakage into the luminaire can connect the LED output to the metal enclosure of luminaire. The luminaire then becomes unsafe because the non-isolated driver will directly pass the energy to the surface, such as a metal enclosure, of the luminaire. This is a fatal issue if a person touches the surface of a working luminaire as shown by symbol 20. The power can then flow through the human body (illustrated by the hand icon), via the earth and back to the mains supply 12.

FIG. 2 shows the approach of the invention. The driver 14 has a non-isolated converter 15 and a protection circuit 30. The protection circuit is provided inside the luminaire, in particular between the non-isolated converter 15 and the LED unit 16. Thus, the non-isolated converter 15 and the protection circuit 30 are integrated as a non-isolated driver 14 according to embodiments of the invention.

FIG. 3 shows in simplified form the functions of the protection circuit 30.

The protection circuit comprises a common mode current detection unit 40, which measures a leakage current to ground. This may be a common mode detection coil, or a sensing resistor with current comparator. Please note that the term “common mode” intends to mean that the detected current difference is leaked away via the ground.

The output from the common mode current detection unit 40 is amplified by an amplifier circuit 42. The leakage current to the ground is typically mA level, but the detected signal corresponding to the leakage current is a small proportional signal, if sensed by a coil, and so preferably the detected signal undergoes accurate amplification and signal processing to generate a level to be used as a safety indicator.

A stop circuit 44 is used to implement a stop function of the driver 14, for example a switch mode power supply circuit of the driver. This is used to interrupt any connection to the mains. The stop circuit controls a stop switch arrangement 46 such as a relay or power switches between the driver and the LED unit 16. The stop circuit 44 preferably stops operation of the non-isolated converter 15.

The overall protection circuit enables any detected leakage current to be reduced to a safe level to avoid the risk of electric shock to the human body.

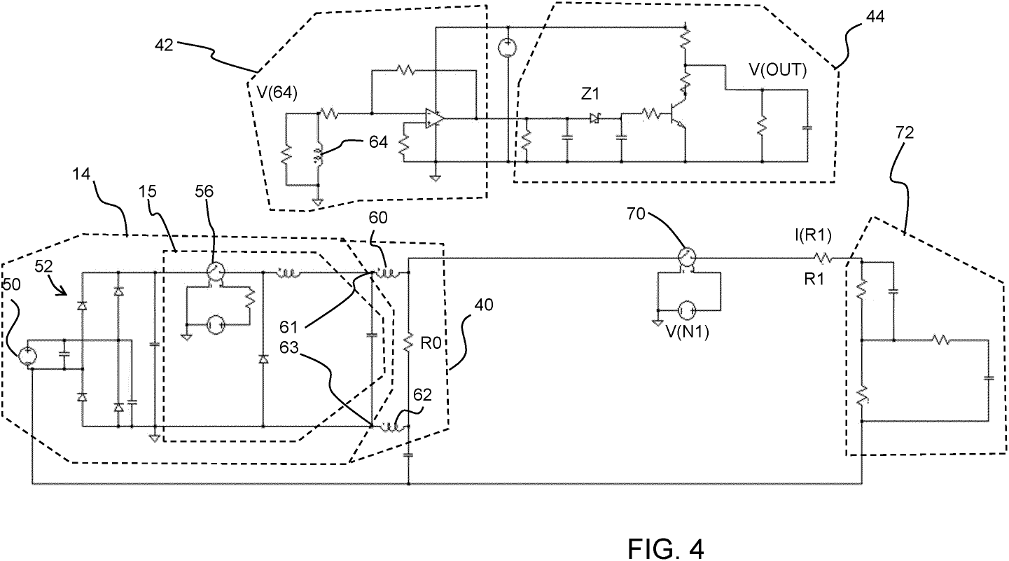

FIG. 4 shows an example of circuit implementation and simulation of human body touch.

The non-isolated driver 14 comprises an AC mains input 50, a full bridge rectifier 52 and the non-isolated converter 15 in the form of a switch mode power converter having a main switch 56. The switch mode power converter comprises a converting circuit, and it may comprise a buck converter as shown in FIG. 4, alternatively it could also be a buck-boost converter or a boost converter for example. The LED load is shown as a resistor R0.

The common mode current detection circuit is shown as a pair of inductors 60, 62 with each in series with a respective one of the two outputs from the driver 14. These inductors form a zero current transformer. The inductors detect a magnetic field resulting from unequal delivered and returned currents. The output of the zero current transformer is detected as a voltage across resistor which may be in parallel with a sensing coil 64 (shown as part of the amplifier circuit 42) magnetically coupled to the inductors 60 and 62.

The output of the non-isolated converter 15 (i.e. a first output for delivering current through inductor 60 and a second output for receiving returned current through inductor 62) is provided to the LED lighting unit R0. The inductors 60, 62 form a sense circuit coupled to both the first output and the second output.

The amplifier circuit 42 amplifies the voltage V(64) across the sensing coil 64 to generate an amplified output which is provided to the stop circuit. The downstream filtering and base-driving circuit 44 provides a clean stop signal.

A ground fault is simulated by switch 70, controlled by voltage signal V(N1) for the purposes of simulation, as well as the resistive-capacitive human body simulation circuit 72 to mimic human body impedance. This provides connection to ground through the resistive-capacitive human body simulation circuit 72. A current I(R1) through resistor R1 represents the body conduction current. R1 could for example be 1 Ohm.

The stop circuit 44 applies a threshold (using Zener diode Z1) and the output from the Zener diode is used to drive the base of a pull down transistor T1. While the threshold is not met (so there is no safety issue detected), the transistor T1 is turned off, and the stop signal V(OUT) is pulled high. When the threshold is met, the transistor T1 is turned on and the stop signal V(OUT) is pulled low.

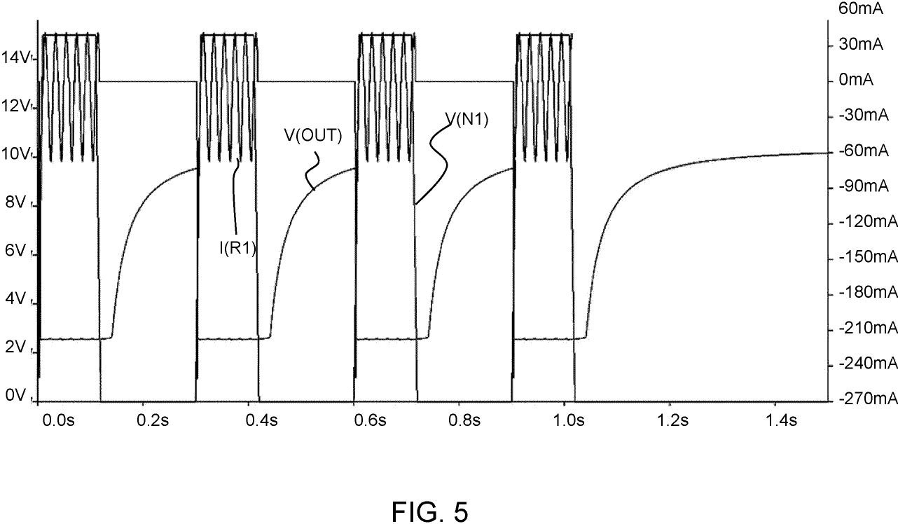

FIG. 5 shows simulation results, and shows the leakage current I(R1) (using the right hand scale), the control signal V(N1) (wherein high represents body contact and low represents body isolation) and the stop signal V(OUT) where a low value is indicative of a safety issue and a high value is indicative of no safety issue. The voltages use the left hand scale. Thus, a low stop signal indicates that a safety interrupt is needed. The human body current is seen to oscillate about zero with a magnitude of around 50 mA.

The results show the correct circuit operation that the stop signal is present while a leakage is simulated.

This driver of the invention thus makes use of a sense circuit within the driver for enabling leakage current, and hence ground fault, detection. A standard non-isolated driver 14 may be used without modification. Similarly, the sense circuit may be before the input of the LED lighting unit 16 so that a standard LED board may also be used.

A ground fault which may be caused by human body conduction may be concluded if the current difference through the inductors 60, 62 is above a lower threshold. The lower threshold is for example between 1 mA and 10 mA, for example 5mA. There may also be an upper threshold at which protection switching should be implemented. The upper threshold corresponds to a safety threshold and is for example between 10 mA and 50 mA, for example 20 mA.

These current represent the difference between the currents through the coils 60, 62 rather than the current I(R1).

The current passing through the human body could greatly exceed the safety level (which in the IEC standard is 20 mA) if it is a very short pulse. The simulation of FIG. 5 shows a 50 mA peak current (~35 mA rms) based on the particular human body simulation and the mains input. The circuit will activate the protection if the current exceeds 20 mA rms within 200 ms. Within that 200 ms window, the peak current may be much higher than 20 mA.

A condition of no ground fault is for example concluded if the current difference is below a the lower threshold, for example 1mA.

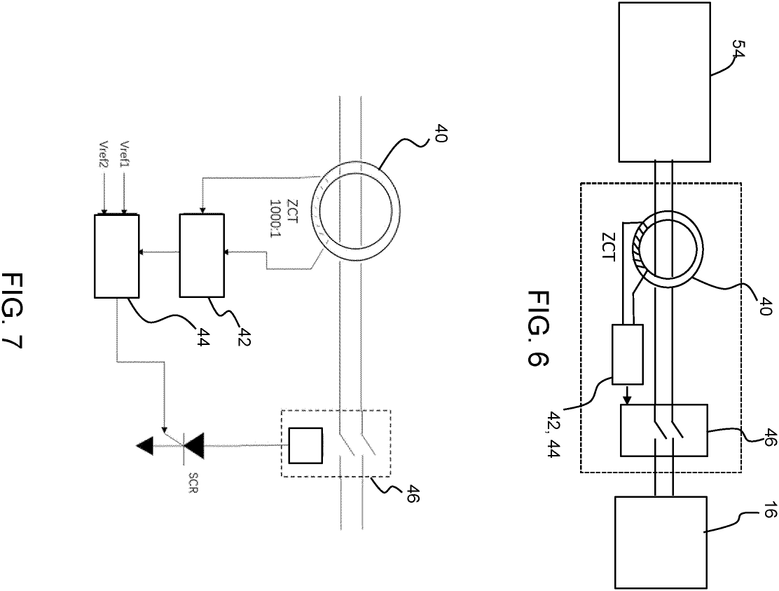

FIG. 6 shows a first example of how the stop signal V(OUT) is used. The common mode detecting circuit 40 is shown as a Zero Current Transformer. The stop switch 46 comprises a respective switch in series with each output line from the non-isolated converter 15, between the non-isolated converter 15 and the LED unit 16.

The switches may be implemented as relays or Mosfets.

During normal operation of the circuit, the leakage current will be less than 1mA due to the normal parasitic capacitances in the system. When there is a leakage to a human touch, 20 mA to 30 mA is considered as a dangerous leakage current to the human body. The circuit should for example start protection at a threshold which lies between 5mA and 20 mA in 200 ms.

FIG. 7 shows a relay based solution in more detail. The stop circuit 44 is shown with two reference values Vref1, Vref2. A silicon controlled rectifier SCR is used to actuate the relay 46 when the voltage falls above the Vref2. A condition of no ground fault is concluded when the voltage falls below Vref1.

There may of course be only a single reference level, below which a no fault condition is concluded and above which protection is implemented.

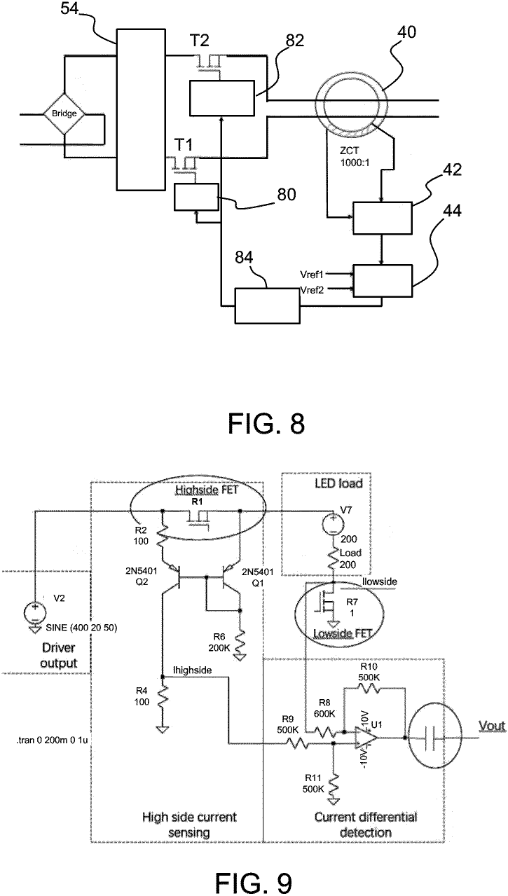

FIG. 8 shows a MOSFET based solution in more detail, and the difference is that the cut off switch is before the ZCT while in the previous embodiment the cut off switch is after the ZCT. Transistors T1 and T2 are in series with the two outputs from the non-isolated converter 15. The first transistor T1 has a first driver 80 and the second transistor T2 has a level shift driver 82. If there is a leakage in the way the system is connected, the protection may be triggered but the trigger signal will then be cancelled since the protection stops the leakage. The result could be light flickering. To avoid this, this circuit also includes a lock circuit 84 that keeps the two MOSFETs cut off until the power is turned off and on again (i.e. a reset). The lock circuit locks the cut off between the driver and the LED unit and avoids this light flicker.

The safety protection identifies particular leakage current conditions and implements protection within defined timings. The system should avoid false triggering. There is always high-frequency (>10 kHz) noise in the environment. The high-frequency noise will not result in safety issue and therefore also should not trigger the protection. Filtering can be used to filter out the high frequency noise.

In the above embodiment, the difference between the positive flow-in current and the negative flow-out current is analyzed to determine whether there is human body-caused leakage. in some implementations, the sensing components are not that unified. For example, in one embodiment, the safety switches themselves are also used as the sensing component wherein their on resistance is used to sense the current flow through.

As shown in FIG. 9, the highside MOSFET may correspond to the MOSFET T2 in FIG. 8; and the lowside MOSFET may correspond to the MOSFET T1 in FIG. 8. They both have on resistance when they are conducting. The invention could use the voltage across the two MOSFETs to reflect the current, but the component variance may be so large that their on resistances are so different to result in a so large voltage difference occurs, even if the current are the same which may cause mis-detection and mis-protection.

In order to solve this, the embodiment of the invention proposes that to analyze the alternating component of the voltage difference. This is based on a fact that the output of the LED driver is DC, both in positive line and in negative line. The ground leakage is from either of the two lines to the protection earth, which is coupled to the neutral of the AC. Thus the voltage potential of the ground is alternating. If there is a leakage from the LED board to the neutral, the leakage current would have an alternating amplitude; thus the difference of currents on highside MOSFET and lowside MOSFET has an alternating component.

The embodiment in FIG. 8 calculates and amplifies the difference by using the op-amp U1, and using a capacitor at the output of the op-amp U1 to output the alternating component, if any. If the alternating component is detected, preferably above a certain threshold, the controller determines that there is a ground fault.

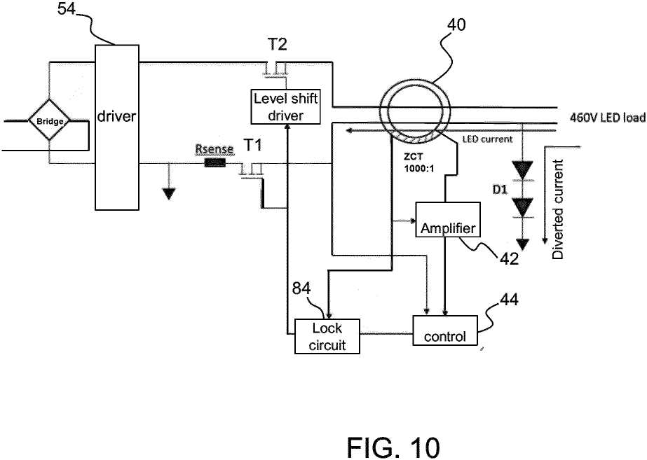

FIG. 10 shows an overcurrent protection by re-using the ground leakage protection circuit of the embodiment of the invention.

Like mentioned above, the invention is based on a non-isolated driver circuit with leakage protection function like FIG. 8 shows.

Its basic operation relies on ZCT (zero current transformer) which detect the current difference between two output wires. Then the signal been amplified by amplifier 42 and compared by the comparator 44 with preset level, if large enough, the comparator 44 will send the cut off signal out to trigger the lock circuit 84 and shut off two FETs T1 and T2 which in series with output wire.

Since leakage protection circuit already include the cut off function which shut off two FETs to isolate the driver output from input, it can be reused for over current/ short circuit protection.

Here is how this embodiment works, an impedance is necessary to connect in series on the output wire (normally low side) to detect the output current (LED current) if output current go higher the voltage on impedance also become higher. The impedance can be a dedicated resistor Rsense. Alternatively, it can also be replaced by MOSFET T1’s internal on resistance. Even further, it can be a combination of resistor Rsense and MOSFET T1’s on resistance. It depends on protection accuracy requirement

A voltage triggered circuit shown as D1 (it can be one or more than two diodes in series, or other current bypass circuit) connected between the cathode of LED unit and ZCT to driver internal GND, meaning the second output of the non-isolated driver. Therefore, this voltage triggered circuit is effectively in parallel with the impedance and the sense circuit. In one embodiment, the resistance of the sense circuit is normally very small. Alternatively, the resistance of the sense circuit can be an unneglectable value, and this that case it counts together with the resistance of the resistor Rsense and on resistance of the MOSFET T1.

At normal situation, the nominal operating current (for example 0.5 A) flow to driver output and generate 0.25 V on Rsense (for example 0.5 ohm). This voltage is also applied on diode D1, since 0.25 is lower than 0.7 V, the D1 is off and no current flow through diode. If at over current / short situation, output current quickly increase to 2 A, the voltage on Rsense should be 1 V, but since D1 conduct and start flow current, the voltage is clamped to 0.7 V.

Since the diode D1 is connected after the ZCT, the current inside D1 flow back to driver directly. ZCT will detect very high error/difference signal between two output wire and feedback this signal to control circuit to judge.

According to the error signal amplitude, the control circuit can determine how fast to trigger the protection. Normally, >10 mA leakage requires <10 ms protection, higher over current requires quicker response to prevent driver damage.

If short circuit situation, there will be very high current >10 A at very short time. There will be very high signal generated on output of ZCT and this signal could send to lock circuit to trigger protection immediately (skip amplifier and control circuit).

The controller 44 may cut off the driver from the LED unit by turning off the two MOSFETs T1 and T2, in case that it judges an overcurrent occurs.

Here, D1 (diode forward voltage is not that accurate) could be replaced by any other circuit which can bypass the current when output current (namely voltage across the impedance) higher than limit. In a simple embodiment, D1 can be replaced by Zener diode. A more sophisticated implementation could be a voltage comparator to compare the real time voltage on the impedance with a voltage reference corresponding to voltage on the impedance given the overcurrent applied thereon, and a switch, connected in the same position of the diode D1, to be turned on by the voltage comparator when the real time voltage exceeds the voltage reference, to divert the current into the sense circuit/ZCT.

Variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality.

The mere fact that certain measures are recited in mutually different dependent claims does not indicate that a combination of these measures cannot be used to advantage.

If the term “adapted to” is used in the claims or description, it is noted the term “adapted to” is intended to be equivalent to the term “configured to”.

Any reference signs in the claims should not be construed as limiting the scope.

1. A non-isolated drive for a LED lighting unit, comprising:
a non-isolated converter with an input to be connected to a power supply, a converting circuit to convert power from the power supply, and an output arrangement to be connected to the LED lighting unit, wherein said output arrangement comprises a first output for delivering current and a second output for receiving returned current, wherein the output of the non-isolated drive is coupled to the power supply electrically without an electrical isolator;
a sense circuit coupled to both the first output and the second output;
a comparing circuit to compare currents at the first output and the second output and obtain a difference therebetween; and
a controller adapted to determine whether there is a ground fault according to whether an alternating current component of the difference is detected.

2. The driver as claimed in claim 1, wherein the sense circuit comprises an inductor arrangement magnetically coupled to the first output and the second output.

3. The driver as claimed in claim 2, wherein the sense circuit comprises a zero-phase current transformer.

4. The driver as claimed in claim 1, wherein the sense circuit is provided between a first circuit board of the non-isolated converter and a second circuit board of the LED lighting unit, and the controller is adapted to determine whether there is a ground fault at the LED lighting unit according to the difference.

5. The driver as claimed in claim 1, wherein the controller is adapted to identify a ground fault caused by human body conduction if the current difference is above a lower threshold.

6. The driver as claimed in claim 5, wherein the lower threshold is between 1mA and 10mA.

7. The driver as claimed in claim 5, wherein the controller is adapted to determine that a protection function should be implemented if the current difference reaches an upper threshold.

8. The driver as claimed in claim 7, wherein the upper threshold is between 5mA and 50mA.

9. The driver as claim in claim 1, wherein the controller is adapted to determine whether there is the ground fault according to whether the alternating current component of the current difference is no less than a certain threshold.

10. The driver as claimed in claim 5, wherein the controller is adapted to identify no ground fault if the current difference is below the lower threshold.

11. The driver as claimed in claim 1, further comprising a switch arrangement for isolating the first output and the second output, and thereby the LED lighting unit, from the converting circuit if the controller determines a ground fault requiring a protection function.

12. The driver as claimed in claim 11, wherein the switch arrangement comprises a first switch and a second switch, the sense circuit is adapted to sense the difference of the voltages across the first switch and the second switch as the difference of current.

13. The driver as claimed in claim 1, further comprising:
an impedance between the sense circuit and the second output of the non-isolated driver;
a voltage triggered circuit between an interconnection of a cathode of the LED lighting unit and the sense circuit, and the second output,
wherein the voltage triggered circuit is adapted to conduct when a voltage across it exceeds a certain threshold, said voltage is caused by a current exceeding an overcurrent threshold applied on the impedance, and
the voltage triggered circuit, when it conducts, is adapted to divert a current from the sense circuit such that the comparing circuit is adapted to obtain the difference and the controller is adapted to treat the difference effectively as a ground fault and cut off the non-isolated drive from the LED lighting unit.

14. The driver as claimed in claim 13, wherein the impedance comprises a resistor, and the voltage triggered circuit comprises a Zener arrangement whose forward voltage is less than the product of the overcurrent threshold and the resistance of the resistor but larger than the product of a nominal operating current and the resistance of the resistor.

15. A lighting circuit comprising:
the driver as claimed in claim 1; and
the LED lighting unit.
